(19) United States
(12) Patent Application Publication
(10) Pub. No.: US 2026/0009119 A1
(43) Pub. Date: Jan. 8, 2026

(54) METHOD FOR MANUFACTURING MASK

(71) Applicant: Samsung Display Co., Ltd., Yongin-si (KR)

(72) Inventor: Jun Mo IM, Yongin-si (KR)

(73) Assignee: Samsung Display Co., Ltd., Yongin-si (KR)

(21) Appl. No.: 19/226,649

(22) Filed: Jun. 3, 2025

(30) Foreign Application Priority Data
Jul. 2, 2024 (KR) 10-2024-0086922

(51) Int. Cl. C23C 14/04; H10K 71/16

(52) U.S. Cl. CPC C23C 14/042; H10K 71/166

(57) ABSTRACT

A method for manufacturing a mask according to an embodiment includes providing a base layer, forming a pattern layer having a first pattern on the base layer, forming a protective layer on the pattern layer, forming a second pattern on the base layer, and removing the protective layer. The protective layer includes a low-k material.

### CROSS-REFERENCE TO RELATED APPLICATION(S)

This application claims priority to and the benefit of Korean Patent Application No. 10-2024-0086922 under 35 U.S.C. § 119, filed on Jul. 2, 2024, in the Korean Intellectual Property Office, the entire contents of which are incorporated herein by reference.

### BACKGROUND

### 1. Technical Field

The disclosure relates to a method for manufacturing a mask.

### 2. Description of the Related Art

A display panel of a display device includes multiple pixels. Each of the pixels includes a driving element, such as a transistor, and a display element, such as an organic light emitting element. The display element may be formed by laminating electrodes and various functional layers on a substrate.

The functional layers of the display element are formed through a patterning process using a mask having an open area defined to allow material to pass through. The shapes of the patterned functional layers may be controlled by the shape of the mask's open area, and the like. As the resolution of the display panel increases, the mask patterns become finer, and the mask thickness decreases.

### SUMMARY

A technical problem to be solved is to provide a method for manufacturing a mask that can reduce the possibility of damage during a manufacturing process.

A method for manufacturing a mask according to an embodiment may include providing a base layer; forming a pattern layer having a first pattern on the base layer; forming a protective layer on the pattern layer; forming a second pattern on the base layer; and removing the protective layer. The protective layer may include a low-k material.

In an embodiment, the base layer may include silicon.

In an embodiment, a dielectric constant of the low-k material may be less than about 4.

In an embodiment, the low-k material may include at least one material selected from a group consisting of fluorine-doped silicon dioxide, carbon-doped silicon dioxide, porous silicon dioxide, porous carbon-doped silicon dioxide, polyimide (PI), polystyrene (PS), polyethylene (PE), polyvinyl chloride (PVC), polynorbornene, polytetrafluoroethylene (PTFE), benzocyclobutene (BCB), hydrogen silsesquioxane (HSQ), methyl silsesquioxane (MSQ), and a combination thereof.

In an embodiment, the pattern layer may include silicon nitride.

In an embodiment, the forming the pattern layer having the first pattern on the base layer may include forming the pattern layer on the base layer; forming a photosensitive layer having a pattern corresponding to the first pattern on the pattern layer; selectively etching the pattern layer using the photosensitive layer; and removing the photosensitive layer.

In an embodiment, the forming the second pattern on the base layer may include forming a photosensitive layer having a pattern corresponding to the second pattern under the base layer; and selectively etching the base layer using the photosensitive layer.

A method for manufacturing a mask according to another embodiment may include providing a base layer; forming a pattern layer having a first pattern on the base layer; forming a first protective layer on the pattern layer; forming a second protective layer on the first protective layer; forming a second pattern on the base layer; and removing the first protective layer and the second protective layer. The first protective layer may include a low-k material.

In an embodiment, the base layer may include silicon.

In an embodiment, a dielectric constant of the low-k material may be less than about 4.

In an embodiment, the low-k material may include at least one material selected from a group consisting of fluorine-doped silicon dioxide, carbon-doped silicon dioxide, porous silicon dioxide, porous carbon-doped silicon dioxide, polyimide (PI), polystyrene (PS), polyethylene (PE), polyvinyl chloride (PVC), polynorbornene, polytetrafluoroethylene (PTFE), benzocyclobutene (BCB), hydrogen silsesquioxane (HSQ), methyl silsesquioxane (MSQ), and a combination thereof.

In an embodiment, a dielectric constant of a material forming the second protective layer may be greater than a dielectric constant of a material forming the first protective layer.

In an embodiment, the pattern layer may include silicon nitride.

In an embodiment, the forming the pattern layer having the first pattern on the base layer may include forming the pattern layer on the base layer; forming a photosensitive layer having a pattern corresponding to the first pattern on the pattern layer; selectively etching the pattern layer using the photosensitive layer; and removing the photosensitive layer.

In an embodiment, the forming the second pattern on the base layer may include forming a photosensitive layer having a pattern corresponding to the second pattern under the base layer; and selectively etching the base layer using the photosensitive layer.

In an embodiment, the removing the first protective layer and the second protective layer may include peeling off the first protective layer from the pattern layer using a laser lift-off (LLO) process.

In an embodiment, an electronic device comprising a display panel which includes functional layers to display images, wherein the functional layers are formed through a processing process using the mask manufactured according to the method.

In an embodiment, the electronic device may be at least one of a flat panel display, a curved display, a computer monitor, a medical monitor, a television, a billboard, an indoor light, an outdoor light, an indoor signaling light, an outdoor signaling light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall with multiple displays tiled together, a theater screen, a stadium screen, a phototherapy device, or a signboard.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic cross-sectional view of a deposition apparatus.

FIG. 2 is a schematic plan view of a display panel formed using the deposition apparatus.

FIG. 3 is a schematic cross-sectional view taken along line I-I′ in FIG. 2.

FIG. 4 is an exploded schematic perspective view illustrating an example of a mask assembly including a mask and a mask frame.

FIGS. 5A to 5D are schematic cross-sectional views illustrating a process for manufacturing a mask according to an embodiment.

FIGS. 6A to 6D are schematic cross-sectional views illustrating a process for manufacturing a mask according to another embodiment.

FIG. 7 is a schematic diagram illustrating area A in FIG. 6C in more detail.

FIG. 8 is a schematic diagram explaining a protective layer used in a process for manufacturing a mask according to another embodiment.

FIG. 9 is a schematic diagram illustrating area B in FIG. 8 in more detail.

FIGS. 10A to 10E are schematic cross-sectional views illustrating a process for manufacturing a mask according to another embodiment.

FIG. 11 is a schematic flowchart illustrating a method for manufacturing a mask according to an embodiment.

FIG. 12 is a schematic flowchart illustrating a method for manufacturing a mask according to another embodiment.

FIGS. 13 and 14 are a perspective view illustrating an electronic device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, sizes, thicknesses, ratios, and dimensions of the elements may be exaggerated for ease of description and for clarity. Like reference numbers and/or reference characters refer to like elements throughout.

As used herein, the singular forms “a,” “an,” and “the” are intended to include the plural forms as well, unless the context clearly indicates otherwise.

In the description, the term “the same” may refer to “substantially the same,” meaning it is sufficiently similar to be considered the same by those skilled in the art. The term “substantially” may be omitted.

As used herein, the term “about” or “approximately” is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that, although the terms “first,” “second,” etc. may be used herein to describe various elements, these elements should not be limited by these terms. These terms are only used to distinguish one element from another. For example, a first element may be referred to as a second element, and similarly, a second element may be referred to as a first element without departing from the scope of the disclosure.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side. Hence, the expression “in a plan view” used herein may mean that an object is viewed in the third z direction from the top. The phrase “in a schematic cross-sectional view” means viewing a cross-section in the first x direction or the second y direction of which the object is vertically cut from the side. The third z direction also can be referred to as a “thickness direction.”

When an element, such as a layer, a region, a portion, or the like, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

It will be understood that when an element (or a layer, a region, a portion, or the like) is referred to as “formed on,” “being on,” “disposed on,” “connected to,” or “coupled to” another clement in the specification, it can be directly formed on, disposed on, connected or coupled to another element mentioned above, or intervening elements may be disposed therebetween. It will be understood that the terms “connected to” or “coupled to” may include a physical or electrical connection or coupling.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

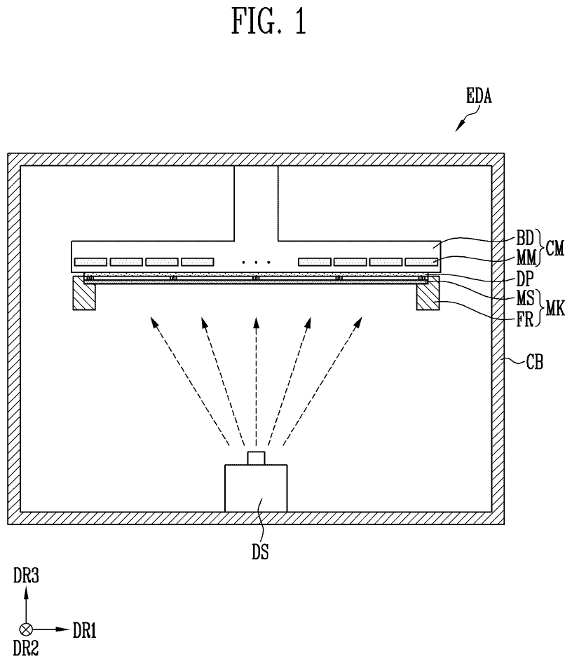

FIG. 1 is a schematic cross-sectional view of a deposition apparatus.

Referring to FIG. 1, a deposition apparatus EDA according to an embodiment may include a deposition chamber CB, a fixing member CM, a deposition source DS disposed inside the deposition chamber CB, and a mask assembly MK disposed inside the deposition chamber CB. Although not shown, the deposition apparatus EDA may further include a mechanical device for implementing an inline system.

The deposition chamber CB may be set to vacuum deposition conditions. The deposition chamber CB may include a bottom surface, a ceiling surface, and side walls. The bottom surface of the deposition chamber CB may be parallel to a plane defined by a first direction DR1 and a second direction DR2. A normal direction to the bottom surface of the deposition chamber CB may be indicated as a third direction DR3.

The fixing member CM may be disposed inside the deposition chamber CB, may be disposed above the deposition source DS, and may fix the mask assembly MK. The fixing member CM may be installed on the ceiling surface of the deposition chamber CB. The fixing member CM may include a jig or a robot arm that holds the mask assembly MK.

The fixing member CM may include a support member BD and magnetic bodies MM coupled to the support member BD. The support member BD may include a plate as a basic structure for fixing the mask assembly MK, but this is not limited thereto. The magnetic bodies MM may be disposed inside or outside the support member BD. The magnetic bodies MM may fix the mask assembly MK with magnetic force.

The deposition source DS may evaporate a deposition material so that the deposition vapor is discharged. The deposition vapor may pass through the mask assembly MK and may be deposited on a display panel DP in a selected pattern. The display panel DP may be defined as a substrate during intermediate processes for manufacturing the completed display panel DP to be described later.

The mask assembly MK may be disposed inside the deposition chamber CB, may be disposed above the deposition source DS, and may support the display panel DP. The display panel DP may include a glass substrate or a plastic substrate. The display panel DP may include a polymer layer disposed on a base substrate.

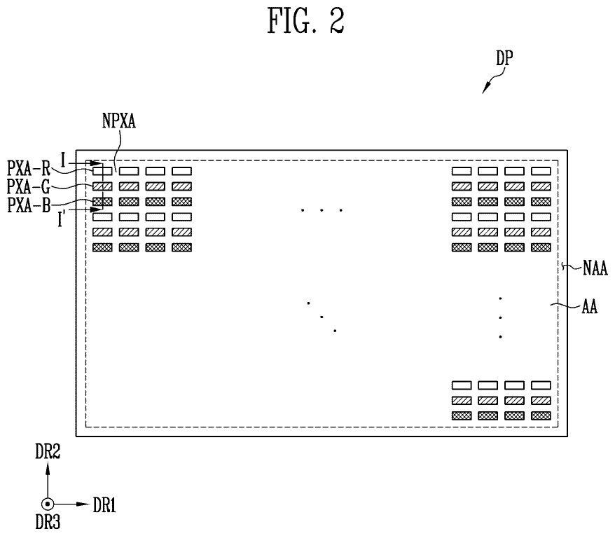

FIG. 2 is a schematic plan view of a display panel formed using the deposition apparatus. More specifically, FIG. 2 is a schematic plan view of the display panel DP manufactured through the deposition apparatus EDA (see FIG. 1). A deposition process may be performed while multiple display panels DP are disposed on the mask assembly MK shown in FIG. 1.

Referring to FIG. 2, the display panel DP according to an embodiment may include an active area AA and a peripheral area NAA. The display panel DP may include a first light emitting area PXA-R, a second light emitting area PXA-G, and a third light emitting arca PXA-B, which are distinct from each other within the active area AA. For example, the first light emitting area PXA-R may be a red light emitting area that emits red light, the second light emitting area PXA-G may be a green light emitting area that emits green light, and the third light emitting area PXA-B may be a blue light emitting area that emits blue light.

The first to third light emitting areas PXA-R, PXA-G, and PXA-B may not overlap each other and may be distinct from each other when viewed in a plan view defined by the first direction DRI and the second direction DR2. An area between adjacent light emitting areas PXA-R, PXA-G, and PXA-B may be defined as a non-light emitting area NPXA.

The display panel DP shown in FIGS. 1 and 2 may include at least one functional layer manufactured using a mask MS. For example, a functional layer in the form of a ‘common layer’ that overlaps all the light emitting areas PXA-R, PXA-G, and PXA-B among functional layers included in the display panel DP may be provided using the mask MS.

According to an embodiment, the light emitting areas PXA-R, PXA-G, and PXA-B of the display panel DP may be arranged in a stripe shape. For example, multiple first light emitting areas PXA-R, multiple second light emitting areas PXA-G, and multiple third light emitting areas PXA-B may be arranged alternately along the first direction DR1, and light emitting areas that provide light of the same color may be spaced apart from each other along the second direction DR2.

The arrangement of the light emitting areas PXA-R, PXA-G, and PXA-B is not limited thereto, and the order in which the first light emitting area PXA-R, the second light emitting area PXA-G, and the third light emitting area PXA-B are arranged may vary depending on the characteristics of the display quality required by the display panel DP.

For example, the light emitting areas PXA-R, PXA-G, and PXA-B may have a PENTILE™ structure in the form of a diamond array. The sizes of the light emitting areas PXA-R, PXA-G, and PXA-B may be different from each other, and their arrangement and size may be adjusted or modified in various ways according to the characteristics of the display quality required by the display panel DP.

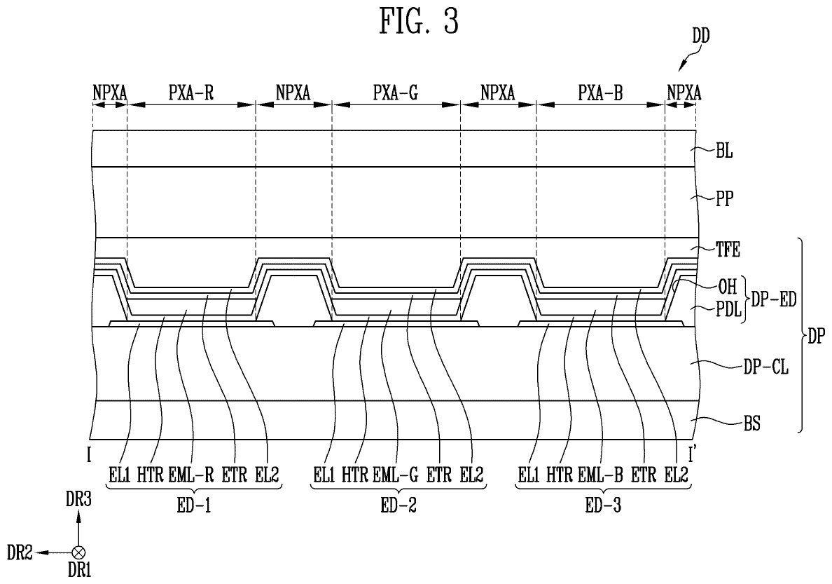

FIG. 3 is a schematic cross-sectional view taken along line I-I′ in FIG. 2.

Referring to FIG. 3, the display panel DP formed using the deposition apparatus EDA (see FIG. 1) may be combined with an optical layer PP and a cover substrate BL disposed on the display panel DP to form a display device DD. The display panel DP may include multiple light emitting elements ED-1, ED-2, and ED-3. The optical layer PP may be disposed on the display panel DP to control light reflected from the display panel DP due to external light. The optical layer PP may include, for example, a polarizing layer or a color filter layer. In other embodiments, the optical layer PP may be omitted from the display device DD.

The cover substrate BL may be disposed on the optical layer PP. The cover substrate BL may provide a base surface for the optical layer PP. The cover substrate BL may be an inorganic layer, an organic layer, or a composite material layer. In other embodiments, the cover substrate BL may be omitted.

In an embodiment, the display panel DP may include a base layer BS, a circuit layer DP-CL provided on the base layer BS, and a display element layer DP-ED. The display element layer DP-ED may include the light emitting elements ED-1, ED-2, and ED-3. The display panel DP may include an encapsulation layer TFE disposed on the display element layer DP-ED.

In an embodiment, the display panel DP may be an organic electroluminescence display panel including an organic electroluminescence element in the display element layer DP-ED. For example, the mask MS (see FIG. 1) may be used when forming a portion of the functional layer of the display element layer DP-ED of the organic electroluminescence display panel.

In an embodiment, the circuit layer DP-CL may be disposed on the base layer BS, and the circuit layer DP-CL may include multiple transistors. Each of the transistors may include a control electrode, an input electrode, and an output electrode. The circuit layer DP-CL may include multiple insulating layers.

The encapsulation layer TFE may cover the light emitting elements ED-1, ED-2, and ED-3. The encapsulation layer TFE may seal the display element layer DP-ED. The encapsulation layer TFE may be a thin film encapsulation layer.

Each of the light emitting elements ED-1, ED-2, and ED-3 may include a first electrode EL1, a hole transport region HTR, a light emitting layer EML-R, EML-G, or EML-B, an electron transport region ETR, and a second electrode EL2.

The first electrode ELI of each of the light emitting elements ED-1, ED-2, and ED-3 may be exposed at least in part through a display opening OH defined by a pixel defining layer PDL. The light emitting layer EML-R, EML-G, or EML-B may be disposed within the display opening OH, and the hole transport region HTR, the electron transport region ETR, and the second electrode EL2 may be provided as common layers across the light emitting elements ED-1, ED-2, and ED-3.

At least one of the hole transport region HTR, the electron transport region ETR, and the second electrode EL2 provided as common layers in the light emitting elements ED-1, ED-2, and ED-3 of the display panel DP may be formed using the mask MS.

Some of insulating layers included in the circuit layer DP-CL or the encapsulation layer TFE disposed on the light emitting elements ED-1, ED-2, and ED-3 may also be formed using the mask MS.

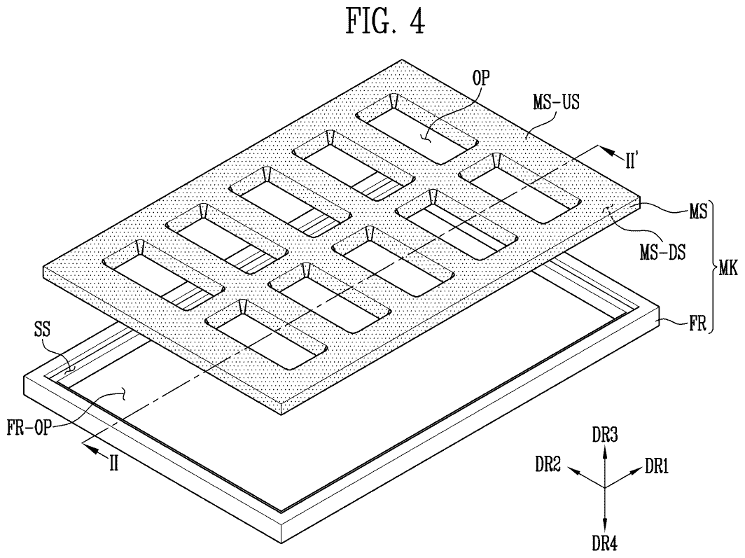

FIG. 4 is an exploded schematic perspective view illustrating an example of a mask assembly, including a mask and a mask frame. In FIG. 4, a direction opposite to the first direction DR1 may be defined as a fourth direction DR4.

Referring to FIG. 4, the mask assembly MK may include the mask MS and a mask frame FR. In an embodiment, the mask assembly MK may be used to form a common layer of the same material on a target substrate, which functions as a deposition surface. In an embodiment, the mask assembly MK may include an open mask for a thin film process used to form the functional layer as a thin film. The open mask for a thin film process may be used to laminate a thin film layer of the same material across a single display device on the target substrate.

The mask frame FR may support the mask MS. For example, the mask frame FR may have a frame opening FR-OP defined on the inside, and the mask MS may be disposed within the frame opening FR-OP. More specifically, the mask frame FR may have an upper surface and a lower surface that are perpendicular to the third direction DR3. The frame opening may be defined by multiple inner surfaces that are perpendicular to the upper surface. These inner surfaces defining the frame opening may also be perpendicular to the lower surface.

The mask frame FR may support an edge portion of the mask MS. In an embodiment, the mask frame FR may be disposed under the mask MS. The mask MS may be mounted on the mask frame FR. For example, the mask frame FR may include a support surface SS that supports the mask MS on the inside, where the frame opening FR-OP is defined, and the mask MS may be disposed on the support surface SS. However, embodiments are not limited thereto. The mask frame FR may also be disposed on edges of upper and lower surfaces of the mask MS to support the mask MS. In an embodiment, the mask MS may be fixed to the mask frame FR.

The mask frame FR may be formed of a metal material, including at least one of iron (Fc) and nickel (Ni). For example, the mask frame FR may include an alloy of iron and nickel. The mask frame FR may be manufactured from stainless steel (SUS), Invar, or the like.

The mask MS may include at least one open area OP. In an embodiment, the mask MS may include multiple open areas OP spaced apart from each other in a plan view.

The multiple open areas OP may be aligned in a plane defined by a first direction DRI and a second direction DR2. FIG. 4 shows an embodiment of the mask MS in which five open areas OP are spaced apart from each other along the first direction DR1 and two open areas OP are spaced apart from each other along the second direction DR2. However, this is just an example, and the number of open areas OP is not limited to that shown in the drawing. The open areas OP may be arranged at regular intervals along either the first direction DR1 or the second direction DR2. A material for forming the functional layer, such as a common layer, may be deposited onto the target substrate through each of the multiple open areas OP.

In an embodiment, the mask MS may have a plate shape extending along the first direction DR1 and the second direction DR2. In an embodiment, the mask MS may have a square shape in a plan view defined by the first direction DR1 and the second direction DR2. However, embodiments are not limited thereto. The shape of the mask MS may vary depending on the shape of the target substrate, which functions as the deposition surface, the shape of the mask frame FR that supports the mask MS, or the like.

In the mask MS according to an embodiment, the open areas OP may have a square shape in a plan view. However, embodiments are not limited thereto. The shape of the open areas OP may be modified to have various shapes depending on the shape of functional layers formed on the target substrate.

The mask MS may include a lower surface (or first surface) MS-DS and an upper surface (or second surface) MS-US facing each other.

In an embodiment, the mask MS may include a silicon nitride (Sin) thin film. The silicon nitride thin film may be formed through a chemical vapor deposition process, such as plasma enhanced chemical vapor deposition (PECVD), low pressure chemical vapor deposition (LPCVD), or low temperature chemical vapor deposition (LTCVD).

The silicon nitride thin film may have relatively high hardness, and thus may act as a membrane. The silicon nitride thin film may be applied to both sides of a wafer because they have high heat resistance and oxidation resistance.

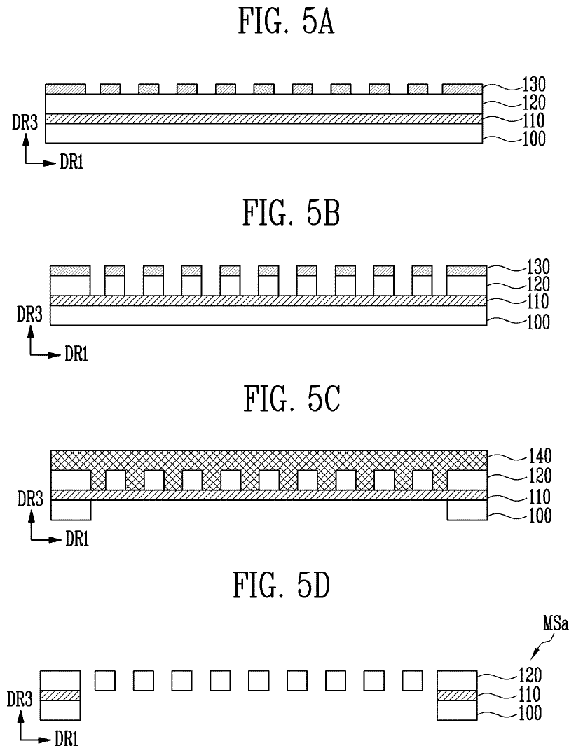

FIGS. 5A to 5D are schematic cross-sectional views illustrating a process for manufacturing a mask according to an embodiment.

Referring to FIG. 5A, a first base layer 100 may be provided for manufacturing a mask MS. In an embodiment, the first base layer 100 may include silicon and may be provided as a silicon wafer. A second base layer 110 may be formed on the first base layer 100. In an embodiment, the second base layer 110 may include a material from silicon oxide family. A pattern layer 120 may be formed on the second base layer 110. In an embodiment, the pattern layer 120 may include silicon. A photosensitive layer 130 may include a target pattern for etching the pattern layer 120. The photosensitive layer 130 may be formed to correspond to a final pattern of the mask MS. A photolithography process may be applied to form the photosensitive layer 130 shown in FIG. 5A. For example, a photosensitive agent may be applied onto the pattern layer 120, and the pattern of the mask MS may be formed on the photosensitive agent through an exposure process. After that, the photosensitive layer 130 may be formed by removing unnecessary portions of the photosensitive agent using a developer. A hard bake process may be performed on the photosensitive layer 130 to prepare it for a subsequent etching process.

Referring to FIG. 5B, an etching process may be performed on the pattern layer 120. Through the etching process, a pattern corresponding to the pattern of the photosensitive layer 130 may be formed on the pattern layer 120.

Referring to FIG. 5C, the photosensitive layer 130 may be removed to expose the pattern layer 120, and a protective layer 140 may be formed on the pattern layer 120. The protective layer 140 may protect the pattern layer 120 on an upper surface of the second base layer 110.

An etching process may be performed on a lower surface of the first base layer 100. A photosensitive layer having a pattern may be formed on the lower surface of the first base layer 100 using a photolithography process, followed by an etching process to remove unnecessary portions of the first base layer 100. Accordingly, as shown in FIG. 5C, the first base layer 100 may have an opening.

Referring to FIG. 5D, a portion of the second base layer 110 corresponding to the opening of the first base layer 100 may be etched and removed. Thereafter, the protective layer 140 may be removed to expose the pattern layer 120, thereby completing a mask MAs. The mask MAs shown in FIG. 5D may represent one embodiment of the mask MS shown in FIG. 4. FIG. 5D may be a schematic cross-sectional view taken along line II-II′ in FIG. 4. However, in FIG. 5D, only the mask from FIG. 4 is shown, and the mask frame is omitted.

Referring to FIG. 5D, the pattern layer 120 may act as a thin film that forms the pattern of the mask MAs. In the case where the pattern layer 120 is thick, forming a fine pattern on the display panel may be difficult. As the resolution of the display panel increases, the pattern of the mask MAs needs to be finer, and the thickness of the pattern layer 120 needs to be reduced. Accordingly, a defect in which the pattern layer 120 is damaged may occur during a process of removing the protective layer 140 in a manufacturing process of the mask MAs.

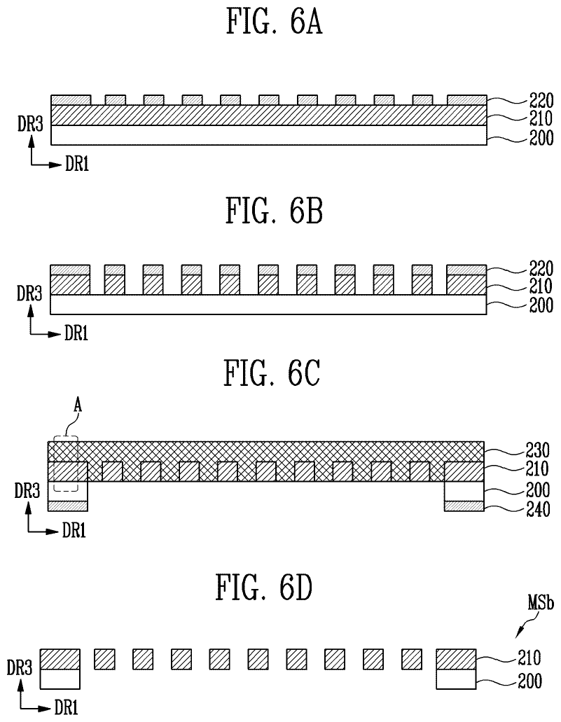

FIGS. 6A to 6D are schematic cross-sectional views illustrating a process for manufacturing a mask according to another embodiment.

Referring to FIG. 6A, a base layer 200 may be provided for manufacturing a mask MS. In an embodiment, the base layer 200 may include silicon and may be provided as a silicon wafer. A pattern layer 210 may be formed on the base layer 200. In an embodiment, the pattern layer 120 may be formed of an inorganic film. For example, the pattern layer 210 may include silicon nitride. A photosensitive layer 220 may be formed on the pattern layer 210. The photosensitive layer 220 may include a target pattern for etching the pattern layer 210. A photolithography process may be applied to form the photosensitive layer 220 shown in FIG. 6A.

Referring to FIG. 6B, an etching process may be performed on the pattern layer 210. Through the etching process, a pattern corresponding to the pattern of the photosensitive layer 220 may be formed on the pattern layer 210.

Referring to FIG. 6C, the photosensitive layer 220 may be removed to expose the pattern layer 210, and a protective layer 230 may be formed on the pattern layer 210. The protective layer 230 may protect the pattern layer 210 having the pattern on an upper surface of the base layer 200.

An etching process may be performed on a lower surface of the base layer 200. Specifically, a photosensitive layer 240 having a pattern formed thereon may be formed on the lower surface of the base layer 200 using a photolithography process. The photosensitive layer 240 under the base layer 200 may be formed to have a pattern corresponding to an edge of the mask MS. After the photosensitive layer 240 is formed, an etching process may be performed to remove unnecessary portions of the base layer 200.

Referring to FIG. 6D, the photosensitive layer 240 under the base layer 200 may be removed. In an embodiment, the photosensitive layer 240 may be removed through a dry etching process. During this process, the protective layer 230 on the pattern layer 210 may be removed, exposing the pattern layer 210 and completing a mask MS. The mask MSb shown in FIG. 6D may represent one embodiment of the mask MS shown in FIG. 4. More specifically, FIG. 6D may be a schematic cross-sectional view taken along line II-II′ in FIG. 4. However, in FIG. 6D, only the mask from FIG. 4 is shown, and the mask frame is omitted.

Similar to the mask MSa shown in FIG. 5D, the pattern layer 210 in FIG. 6D may be used as a thin film that forms the pattern of the mask MSa. In the case where the pattern layer 210 is thick, it may be difficult to form a fine pattern on the display panel. As the resolution of the display panel increases, the pattern of the mask MSb needs to be finer, and the thickness of the pattern layer 210 needs to be reduced. Accordingly, a defect in which the pattern layer 210 is damaged may occur during a process of removing the protective layer 230 in a manufacturing process of the mask MSb.

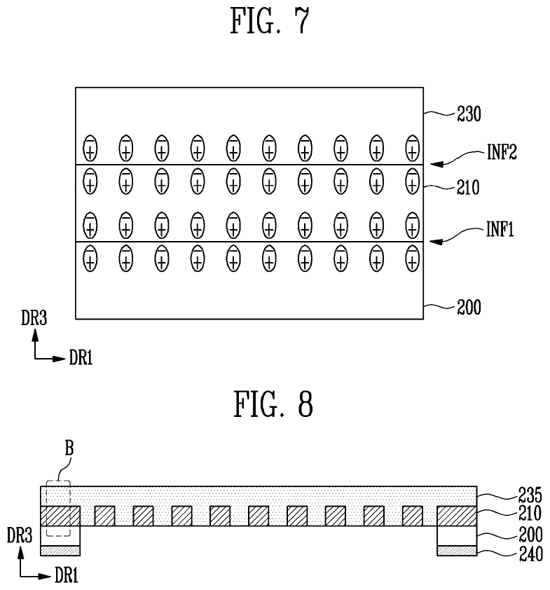

FIG. 7 is a schematic diagram illustrating area A in FIG. 6C in more detail.

Referring to FIG. 7, polarization states of the base layer 200, the pattern layer 210, and the protective layer 230 within area A are shown. The base layer 200 and the pattern layer 210 may be in contact with each other, forming a first interface INF1, and the pattern layer 210 and the protective layer 230 may be in contact with each other, forming a second interface INF2. The polarization state near the first interface INF1 may be determined by the dielectric constant characteristics of the material forming the base layer 200 and the material forming the pattern layer 210, while the polarization state near the second interface INF2 may be determined by the dielectric constant characteristics of the material forming the pattern layer 210 and the material forming the protective layer 230. The polarization state near the first interface INF1 may determine or influence the adhesion strength between the base layer 200 and the pattern layer 210. Similarly, the polarization state near the second interface INF2 may influence the adhesion strength between the pattern layer 210 and the protective layer 230. In the case where the adhesion strength at the first interface INF1 is greater than the adhesion strength at the second interface INF2, the pattern layer 210 may remain stable on the base layer 200 during the process of removing the protective layer 230. In the case where the adhesion strength at the second interface INF2 is greater than the adhesion strength at the first interface INF1, the pattern layer 210 may be peeled off from the base layer 200 during the process of removing the protective layer 230, potentially causing damage to the pattern layer 210.

In the case where a dielectric constant of the material forming the protective layer 230 is high, the polarization-induced coupling between the molecules in the pattern layer 210 and the molecules in the protective layer 230 near the second interface INF2 may be strengthened. Accordingly, the adhesion strength at the second interface INF2 may be greater than the adhesion strength at the first interface INF1. The pattern layer 210 may be peeled off from the base layer 200 during the process of removing the protective layer 230.

According to the method for manufacturing the mask in an embodiment, a low-k material may be used for the protective layer 230. By reducing the adhesion strength at the second interface INF2, the likelihood of damaging the pattern layer 210 during the process of removing the protective layer 230 can be reduced or minimized.

FIG. 8 is a schematic diagram illustrating a protective layer in a process for manufacturing a mask according to another embodiment. Referring to FIG. 8, a protective layer 235 may be formed on the exposed pattern layer 210. However, the protective layer 235 in FIG. 8 may include a low-k material. FIG. 8 may be substantially the same as FIG. 6C, except that the material forming the protective layer 235 is different.

In an embodiment, a low-k material may be defined as a material having a dielectric constant value less than about 4. The dielectric constant of silicon dioxide (SiO₂) may range from about 3.9 to about 4.2, and any material having a dielectric constant lower than silicon dioxide (SiO₂) may be considered as a low-k material. According to an embodiment, a low-k material produced by performing a specific process on silicon oxide or silicon nitride may be used as the protective layer 235.

As an example, the protective layer 235 may include fluorine-doped silicon dioxide, carbon-doped silicon dioxide, porous silicon dioxide, porous carbon-doped silicon dioxide, polyimide (PI), polystyrene (PS), polyethylene (PE), polyvinyl chloride (PVC), polynorbornene, polytetrafluoroethylene (PTFE), benzocyclobutene (BCB), hydrogen silsesquioxane (HSQ), methyl silsesquioxane (MSQ), or a combination of at least two or more of these materials. The above materials are only examples, and embodiments are not limited thereto. The protective layer 235 may also include any material having a dielectric constant of less than or equal to about 4.

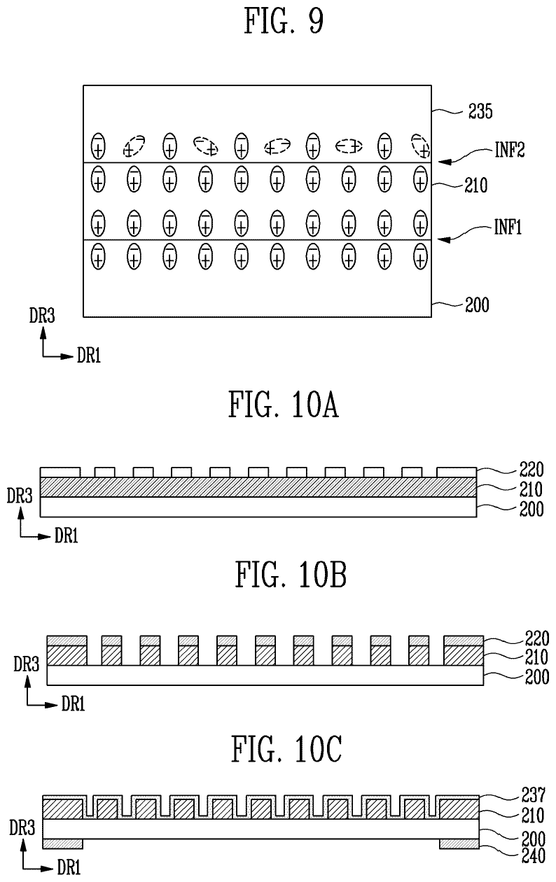

FIG. 9 is a schematic diagram illustrating area B in FIG. 8 in more detail.

Referring to FIG. 9, the polarization states of the base layer 200, the pattern layer 210, and the protective layer 235 within area B are shown. The base layer 200 and the pattern layer 210 may be in contact with each other, defining a first interface INF1, and the pattern layer 210 and the protective layer 235 may be in contact with each other, defining a second interface INF2.

As described above, since a low-k material is used for the protective layer 235, the polarization-induced coupling between the molecules in the pattern layer 210 and the molecules in the protective layer 235 near the second interface INF2 may be relatively weak. Accordingly, in the case where the adhesion strength at the first interface INF1 is greater than the adhesion strength at the second interface INF2, the pattern layer 210 may remain stable on the base layer 200 during the process of removing the protective layer 235. By reducing the adhesion strength at the second interface INF2, the likelihood of damaging the pattern layer 210 during the process of removing the protective layer 235 can be minimized.

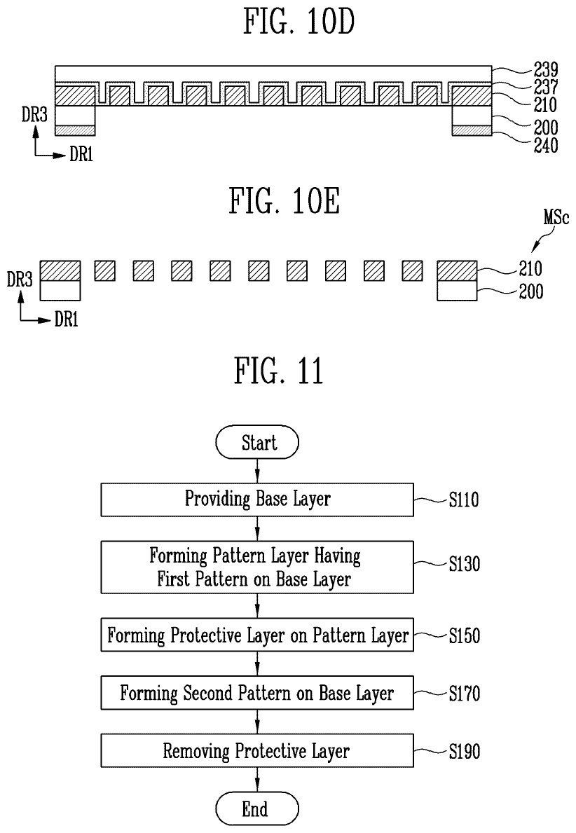

Referring to FIGS. 8 and 9, an embodiment using a low-k material as the material for the protective layer 235 on the pattern layer 210 is described. According to another embodiment, a first protective layer including a low-k material may be formed on the pattern layer 210, and a second protective layer including a material having a relatively high dielectric constant may be formed on the first protective layer. This will be described below with reference to FIGS. 10A to 10E.

FIGS. 10A to 10E are schematic cross-sectional views illustrating a process for manufacturing a mask according to another embodiment.

Referring to FIG. 10A, a base layer 200 may be provided for manufacturing a mask MS. In an embodiment, the base layer 200 may include silicon and may be provided as a silicon wafer. A pattern layer 210 may be formed on the base layer 200. A photosensitive layer 220 may be formed on the pattern layer 210. Referring to FIG. 10B, an etching process may be performed on the pattern layer 210. Through the etching process, a pattern corresponding to the pattern of the photosensitive layer 220 may be formed on the pattern layer 210. FIGS. 10A and 10B may be substantially the same as FIGS. 6A and 6B. Therefore, the description of overlapping contents will be omitted.

Referring to FIG. 10C, the photosensitive layer 220 may be removed to expose the pattern layer 210. A first protective layer 237 may be formed on the exposed pattern layer 210. The first protective layer 237 may include a low-k material, similar to the protective layer 235 described with reference to FIGS. 8 and 9.

Referring to FIG. 10D, a second protective layer 239 may be formed on the first protective layer 237. A dielectric constant of the second protective layer 239 may not be particularly limited. However, in an embodiment, the second protective layer 239 may include a material suitable for protecting the pattern layer 210 during a subsequent etching process, and may have a relatively high dielectric constant. For example, the dielectric constant of the second protective layer 239 may be greater than the dielectric constant of the first protective layer 237.

After the second protective layer 239 is formed, an etching process may be performed on a lower surface of the base layer 200. Specifically, a photosensitive layer 240 having a pattern formed thereon may be formed on the lower surface of the base layer 200 using a photolithography process. The photosensitive layer 240 under the base layer 200 may be formed to have a pattern corresponding to an edge of the mask MS. After the photosensitive layer 240 is formed, an etching process may be performed to remove unnecessary portions of the base layer 200.

Referring to FIG. 10E, the photosensitive layer 240 under the base layer 200 may be removed. In an embodiment, the photosensitive layer 240 may be removed through a dry etching process. During this process, the first protective layer 237 and the second protective layer 239 on the pattern layer 210 may also be removed.

According to an embodiment, a laser may be irradiated to remove the first protective layer 237 on the pattern layer 210. For example, in the case where the first protective layer 237 is formed as a polyimide film, the first protective layer 237 may be peeled off from the pattern layer 210 through a laser lift-off (LLO) process. As the first protective layer 237 is separated from the pattern layer 210, the second protective layer 239 may also be removed.

As described above, since the first protective layer 237 is formed of a low-k material, the pattern layer 210 can be prevented from damage during the process of removing the first protective layer 237 and the second protective layer 239. Once the first protective layer 237 and the second protective layer 239 are removed, the pattern layer 210 may be exposed, and a mask MSc may be finally completed.

FIG. 11 is a schematic flowchart illustrating a method for manufacturing a mask according to an embodiment.

Referring to FIG. 11, a method for manufacturing a mask according to an embodiment may include providing a base layer (S110), forming a pattern layer having a target first pattern on the base layer (S130), forming a protective layer on the pattern layer (S150), forming a second pattern on the base layer (S170), and removing the protective layer (S190).

As described above with reference to FIG. 6A, a base layer 200 may be provided for manufacturing the mask (S110). The step (S130) may be performed as described with reference to FIGS. 6A and 6B. First, as shown in FIG. 6A, a pattern layer 210 may be formed on the base layer 200, and a photosensitive layer 220 may be formed on the pattern layer 210. Thereafter, as shown in FIG. 6B, the target first pattern may be engraved on the pattern layer 210 through an etching process. Thereafter, the photosensitive layer 220 may be removed.

Thereafter, as described with reference to FIG. 8, a protective layer 235 may be formed on the exposed pattern layer 210 (S150). After the protective layer is formed, the second pattern may be formed on the base layer (S170). The step (S170) may be performed as described with reference to FIG. 6C. A photosensitive layer 240 having a second pattern formed thereon may be formed on a lower surface of the base layer 200 using a photolithography process, and an etching process may be performed to remove unnecessary portions of the base layer 200, thereby forming the second pattern on the base layer 200.

After the second pattern is formed on the base layer 200, the protective layer may be removed (S190). Similar to what was described above with reference to FIG. 6D, the photosensitive layer 240 under the base layer 200 on which the second pattern is formed may be removed, and the protective layer 235 on the pattern layer 210 may also be removed. As a result of performing the step (S190), a mask MSb may be completed.

As described above, in the step (S150), the protective layer 235 may be formed using a low-k material. Therefore, during the subsequent step (S190) of removing the protective layer 235, the risk of the pattern layer 150 being damaged can be mitigated.

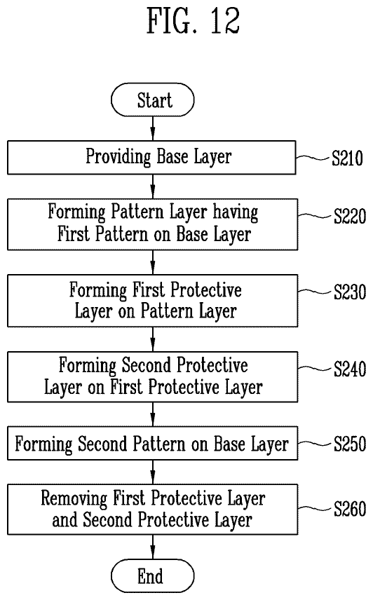

FIG. 12 is a flowchart illustrating a method for manufacturing a mask according to another embodiment.

Referring to FIG. 12, a method for manufacturing a mask according to another embodiment may include providing a base layer (S210), forming a pattern layer having a target first pattern on the base layer (S220), forming a first protective layer on the pattern layer (S230), forming a second protective layer on the first protective layer (S240), forming a second pattern on the base layer (S250), and removing the first protective layer and the second protective layer (S260).

As described above with reference to FIG. 10A, a base layer 200 may be provided for manufacturing the mask (S210). The step (S220) may be performed as described with reference to FIGS. 10A and 10B. First, as shown in FIG. 10A, a pattern layer 210 may be formed on the base layer 200, and a photosensitive layer 220 may be formed on the pattern layer 210. Thereafter, as shown in FIG. 10B, the target first pattern may be engraved on the pattern layer 210 through an etching process. Thereafter, the photosensitive layer 220 may be removed.

Thereafter, as described with reference to FIG. 10C, a first protective layer 237 may be formed on the exposed pattern layer 210 (S230). Thereafter, as described with reference to FIG. 10D, a second protective layer 239 may be formed on the first protective layer 237 (S240).

After the first and second protective layers are formed, a second pattern may be formed on the base layer (S250). The step (S250) may be performed as described with reference to FIG. 10D. A photosensitive layer 240 having a second pattern formed thereon may be formed on a lower surface of the base layer 200 using a photolithography process, and an etching process may be performed to remove unnecessary portions of the base layer 200, thereby forming the second pattern on the base layer 200.

After the second pattern is formed on the base layer 200, the first protective layer 237 and the second protective layer 239 may be removed (S260). As described above with reference to FIG. 10E, the photosensitive layer 240 under the base layer 200 on which the second pattern is formed may be removed, and the first protective layer 237 and the second protective layer 239 on the pattern layer 210 may also be removed. As a result of performing the step (S260), a mask MSc may be completed.

As described above, in the step (S230), the first protective layer 237 may be formed using a low-k material. Therefore, during the subsequent step (S260) of removing the first protective layer 237, the risk of the pattern layer 150 being damaged can be minimized.

According to the method for manufacturing the mask, the possibility of damage to the mask during a manufacturing process can be reduced.

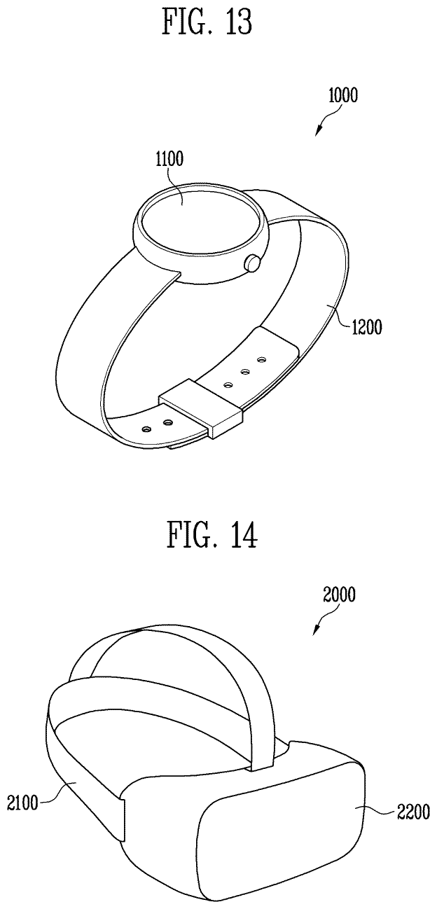

FIG. 13 shows a perspective view of an electronic device formed through a patterning process using a mask according to an embodiment. The electronic device may apply to a smart watch 1000, which includes a display part 1100 and a strap part 1200.

The smart watch 1000 may be a wearable electronic device. For example, the smart watch 1000 may have a structure where the strap part 1200 mounts on a user's wrist.

FIG. 14 illustrates a display system formed through a patterning process using a mask according to an embodiment. The display system may apply to a head-mounted display device 2000.

The head-mounted display device 2000 may be a wearable electronic device that can be worn on a user's head. For example, the head-mounted display device 2000 may be a wearable device for virtual reality (VR) or mixed reality (MR).

The head-mounted display device 2000 may include a head-mounted band 2100 and a display-accommodating case 2200. The head-mounted band 2100 may be connected to the display-accommodating case 2200. The head-mounted band 2100 may include a horizontal band and/or a vertical band used to secure the head-mounted display device 2000 to the user's head. The horizontal band may surround a side portion of the user's head, and the vertical band may surround an upper portion of the user's head. However, embodiments are not limited to this configuration. For example, the head-mounted band 2100 may be implemented as a glasses frame, helmet, or similar structure within the spirit and scope of the disclosure.

The electronic device may include, but is not limited to, a flat panel display, a curved display, a computer monitor, a medical monitor, a television, a billboard, an indoor light, an outdoor light, an indoor signaling light, an outdoor signaling light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall with multiple displays tiled together, a theater screen, a stadium screen, a phototherapy device, or a signboard.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A method for manufacturing a mask comprising:
providing a base layer;
forming a pattern layer having a first pattern on the base layer;
forming a protective layer on the pattern layer;
forming a second pattern on the base layer; and
removing the protective layer, wherein
the protective layer includes a low-k material.

2. The method of claim 1, wherein the base layer includes silicon.

3. The method of claim 1, wherein a dielectric constant of the low-k material is less than about 4.

4. The method of claim 3, wherein the low-k material includes at least one of fluorine-doped silicon dioxide, carbon-doped silicon dioxide, porous silicon dioxide, porous carbon-doped silicon dioxide, polyimide (PI), polystyrene (PS), polyethylene (PE), polyvinyl chloride (PVC), polynorbornene, polytetrafluoroethylene (PTFE), benzocyclobutene (BCB), hydrogen silsesquioxane (HSQ), and methyl silsesquioxane (MSQ).

5. The method of claim 1, wherein the pattern layer includes silicon nitride.

6. The method of claim 1, wherein the forming of the pattern layer having the first pattern on the base layer includes:
forming the pattern layer on the base layer;
forming a photosensitive layer having a pattern corresponding to the first pattern on the pattern layer;
selectively etching the pattern layer using the photosensitive layer; and
removing the photosensitive layer.

7. The method of claim 1, wherein the forming of the second pattern on the base layer includes:
forming a photosensitive layer having a pattern corresponding to the second pattern under the base layer; and
selectively etching the base layer using the photosensitive layer.

8. A method for manufacturing a mask comprising:
providing a base layer;
forming a pattern layer having a first pattern on the base layer;
forming a first protective layer on the pattern layer;
forming a second protective layer on the first protective layer;
forming a second pattern on the base layer; and
removing the first protective layer and the second protective layer, wherein
the first protective layer includes a low-k material.

9. The method of claim 8, wherein the base layer includes silicon.

10. The method of claim 8, wherein a dielectric constant of the low-k material is less than about 4.

11. The method of claim 10, wherein the low-k material includes at least one of fluorine-doped silicon dioxide, carbon-doped silicon dioxide, porous silicon dioxide, porous carbon-doped silicon dioxide, polyimide (PI), polystyrene (PS), polyethylene (PE), polyvinyl chloride (PVC), polynorbornene, polytetrafluoroethylene (PTFE), benzocyclobutene (BCB), hydrogen silsesquioxane (HSQ), and methyl silsesquioxane (MSQ).

12. The method of claim 8, wherein a dielectric constant of a material forming the second protective layer is greater than a dielectric constant of a material forming the first protective layer.

13. The method of claim 8, wherein the pattern layer includes silicon nitride.

14. The method of claim 8, wherein the forming of the pattern layer having the first pattern on the base layer includes:
forming the pattern layer on the base layer;
forming a photosensitive layer having a pattern corresponding to the first pattern on the pattern layer;
selectively etching the pattern layer using the photosensitive layer; and
removing the photosensitive layer.

15. The method of claim 8, wherein the forming of the second pattern on the base layer includes:
forming a photosensitive layer having a pattern corresponding to the second pattern under the base layer; and
selectively etching the base layer using the photosensitive layer.

16. The method of claim 8, wherein the removing the first protective layer and the second protective layer includes:
peeling off the first protective layer from the pattern layer using a laser lift-off (LLO) process.

17. An electronic device comprising a display panel which includes functional layers to display images, wherein the functional layers are formed through a processing process using the mask manufactured according to the method of claim 1.

18. The electronic device of claim 17, wherein the electronic device is at least one of a flat panel display, a curved display, a computer monitor, a medical monitor, a television, a billboard, an indoor light, an outdoor light, an indoor signaling light, an outdoor signaling light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall with multiple displays tiled together, a theater screen, a stadium screen, a phototherapy device. or a signboard.
